(19) United States
(12) Patent Application Publication
(10) Pub. No.: US 2010/0314752 A1
(43) Pub. Date: Dec. 16, 2010

(54) FORMING AN ETCHED PLANARISED PHOTONIC CRYSTAL STRUCTURE

(75) Inventors: Mingbin Yu, Singapore (SG); Ramana Murthy Badam, Singapore (SG); Babu Narayanan, Singapore (SG)

Correspondence Address: PATTERSON THUENTE CHRISTENSEN PEDERSEN, P.A., 4800 IDS CENTER, 80 SOUTH 8TH STREET, MINNEAPOLIS, MN, 55402-2100, US

(73) Assignee: AGENCY FOR SCIENCE, TECHNOLOGY AND RESEARCH, Singapore (SG)

(21) Appl. No.: 12/744,199

(22) PCT Filed: Nov. 22, 2007
(86) PCT No.: PCT/SG07/00401

§ 371 Date: Aug. 16, 2010

(51) Int. Cl. H01L 23/48; H01L 21/283

(52) U.S. Cl. 257/734; 438/597; 257/E21.159; 257/E23.01

(57) ABSTRACT

A method of forming a photonic crystal (PhC) structure and a PhC structure formed by such method. The method comprises forming holes in a Si-based host layer; filling the holes with a high-density plasma (HDP) deposited Si-based oxide and such that a surface of the Si-based host layer is directly covered with the Si-based oxide; performing at least a selective wet etching step for etching the Si-based oxide such that a surface of the resulting PhC structure is planarized.

### FIELD OF INVENTION

The present invention relates broadly to a method of forming a photonic crystal structure, and to a photonic crystal structure fabricated using the method.

### BACKGROUND

Photonic crystal (PhC) is a promising optical device platform to fabricate devices for various wavelengths of light for future photonic discrete devices and integrated circuits. A PhC is an artificial periodic structure with dimensions of a few optical wavelengths and an optical band structure similar to the electron band structure widely used in electronics. It has a frequency band called a photonic band gap (PBG) where light cannot exist. This means that a line defect in a PhC acts as a waveguide and a point defect in a PhC acts as a resonator that does not allow leakage of light.

In recent years, more and more optical functions have been incorporated and combined into photonic integrated circuits (PICs). Currently, the existing PICs combine only a limited number of functions on a single chip, which is limited by larger space required to propagate the light from one functional element to the other through waveguides. In particular, bends in the waveguides prove to be a crucial limitation, as the bending radius needs to be adequately large to prevent radiation losses. Therefore, to increase the level of integration in PICs, it is not only necessary to scale down the individual functional elements, but to reduce the space required for waveguide structures. This demands narrow waveguides that can have tight bends with little loss.

Two-dimensional (2D) PhC slabs in which light is confined by PBG in the in-plane direction and by the difference of refractive index in the thickness direction have been studied in efforts to scale down chip size. Such slabs are easily fabricated by LSI (Large Scale Integration) processes and the structure is similar to a conventional planar light wave circuit.

Recently, there have been studies on reducing the out-plane radiation loss of 2D-PhC devices which have dramatically improved the quality of PhCs. Currently, most of the silicon PhC structures are constituted by a Si host and air holes. However this is not a suitable option to realize true PICs, as it is difficult to implement device integration with such air gap structures. To realize true PICs, it is essential to fabricate air gap-free PhCs with high planarity top surfaces in order to eliminate the bridging (i.e. any residual layer on top of the PhCs that connects them optically) of the optical elements in the devices e.g., wave guides or mode converters. To achieve an air gap-free planar slab with PhCs, it is important to fill the photonic crystal holes and flatten the top surface after the filling. PhCs based Si slab device architectures without air gaps have wide applications in fabricating photonic devices such as Modulators, High ‘Q’ cavities for light sources, and Chromatic dispersion compensators. In addition, a fully CMOS compatible process design and fabrication technique can provide more integrate-ability to realize a variety of such device structures.

One of the key challenges involved in forming the air gap-free structures is the void-free filling of the photonic crystals and subsequent planarization to obtain the optical grade PhC slab. In the conventional STI (Shalow Trench Isolation) process, certain planarization is achieved after filling the trenches with High Density Plasma (HDP) Silicon-di-oxide. However, in STI a silicon nitride layer is used as etch stop for planarization. Moreover, after completing the planarization the formation of a “Divot”, i.e. a non-planar defect adjacent the etch stop, is a drawback in this process.

For PhC slab fabrication, a silicon nitride layer cannot be used as etch stop for planarization and, also, divot formation is unacceptable due to optical sensitivity. More over, the gap filling is to be done inside photonic crystal holes which is more difficult than filling the typically larger trenches in STI. The planarity requirement is verified within the device area, to meet optical grade specifications, making the process highly challenging.

A need therefore exists to provide a PhC slab structure and method of fabricating the same that seeks to address at least one of the above-mentioned problems.

### SUMMARY

In accordance with a first aspect of the present invention there is provided a method of forming a photonic crystal (PhC) structure, the method comprising the steps of forming holes in a Si-based host layer; filling the holes with a high-density plasma (HDP) deposited Si-based oxide and such that a surface of the Si-based host layer is directly covered with the Si-based oxide; performing at least a selective wet etching step for etching the Si-based oxide such that a surface of the resulting PhC structure is planarized.

The host layer may comprise Si.

The Si-based oxide may comprise SiO₂.

The wet etching may comprise an HF etching.

The method may further comprise performing a partial dry etching step prior to the wet etching step.

The dry etching step may comprise a plasma-etching step.

The method may further comprise performing a chemical-mechanical polishing (CMP) step prior to the wet etching step.

The CMP step may be performed prior to the dry etching step.

The method may further comprise forming at least one optical device structure directly on the planarized surface of the PhC structure.

The method may further comprise forming one or more metal contacts directly on the planarized surface of the PhC structure.

The surface of the resulting PhC structure may be planarized to below about 10 nm.

In accordance with a second aspect of the present invention there is provided a PhC structure fabricated using a method as defined in the first aspect.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1a shows the schematic perspective view of a Si photonic crystal slab according to an example embodiment.

FIG. 1b shows a schematic cross-sectional view of the photonic crystal slab of FIG. 1.

FIGS. 2a to d shows schematic cross-sectional views illustrating a method of forming the photonic crystal slab of FIG. 1.

FIG. 3a shows a top view scanning electron microscopy image of HDP oxide filled PhC holes in an example embodiment.

FIG. 3b shows a cross-sectional view scanning electron microscopy image of the HDP oxide filled PhC holes of FIG. 3a.

FIG. 4 shows an atomic force microscopy scan of a PhC slab of an example embodiment.

FIG. 5 shows a top view image of the PhC slab from which the scan in FIG. 4 was taken.

FIG. 6 shows a schematic cross-sectional view of a photonic crystal slab after an initial etching step according to an example embodiment.

FIG. 7 shows a schematic cross-sectional view of the photonic crystal slab of FIG. 6 after a subsequent wet etching step.

FIG. 8a shows a tilted sidewall SEM image of a waveguide formed on a photonic crystal slab according to an example embodiment.

FIG. 8b shows a magnified portion of the image of FIG. 8a.

FIG. 9a shows a transmission electron microscopy analysis cross-sectional view of a waveguide formation on a photonic crystal slab according to an example embodiment.

FIG. 9b shows a magnified portion of the image of FIG. 9a.

FIG. 10 shows an SEM image of a photonic device structure according to an example embodiment.

FIG. 11 shows a flowchart illustrating a method of forming a photonic crystal structure according to an example embodiment.

### DETAILED DESCRIPTION

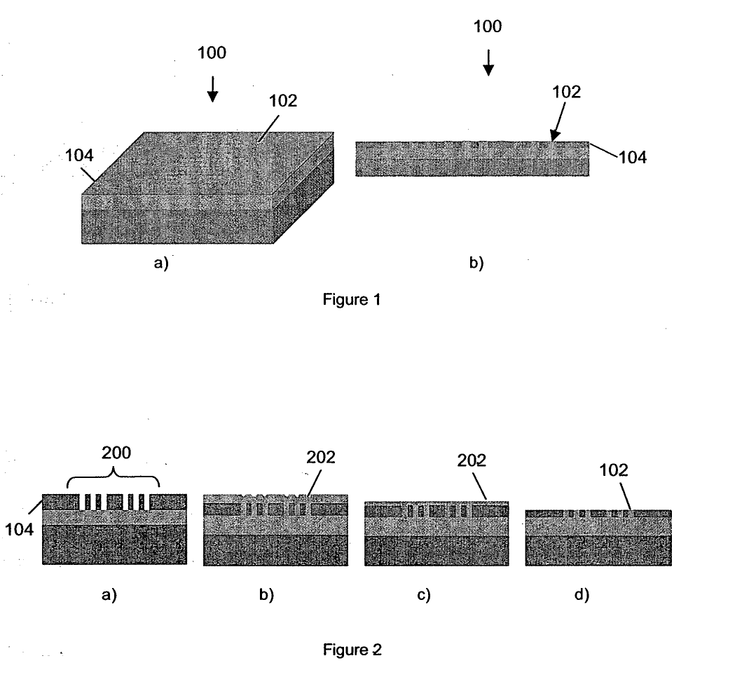

FIGS. 1a and b show schematic perspective and cross-sectional views respectively of a Si photonic crystal slab 100 filled with SiO₂ 102 and planarized according to an example embodiment. The Si/SiO₂ photonic crystal (PhC) layer 103 consists of a two-dimensional triangular or square lattice of SiO₂ pillars 102 embedded in a host Si layer 104 when fabrication of the PhC slab is complete. The unit cells of the triangular or square lattice have a pitch of ˜400 nm. The diameters of the filled SiO₂ pillars 102 inside the holes are in the range of 200 nm to 300 nm and pillar height is in the range of 100 nm to 400 nm in these example embodiments. The thin SOI (Silicon-on-Insulator) Si layer 104 serves as host medium of the PhC layer 103.

The method of forming the PhC slab 100 comprises forming holes in the SOI Si layer followed by filling with silicon di-oxide and final planarization to obtain the PhC slab 100. FIGS. 2a-d show step-by-step process flow schematic drawings for forming the PhC slab 100 in the example embodiment.

A matrix of photonic crystal holes 200 is patterned using 248 nm-Nikon KrF Deep UV lithography as shown in FIG. 2a. Initially, a photo resist of 4100A thickness was coated using a TEL ACT-8 wafer coater track. In order to enable resolving the fine hole structures, a bottom anti reflection coating (BARC) layer was added before coating the photo resist. The diameter of the patterned holes was confirmed using a Hitachi CD SEM S 9200 model. The BARC layer was etched with a N₂/O₂ plasma gas mixture and simultaneously controlling the holes' diameters, in other words the critical dimension (CD). A Reactive Ion Etching (RIE) dry etch process was used to etch the thin top silicon layer 104 for the formation of the photonic crystal holes 200 with smooth and vertical sidewalls. The photonic crystal holes 200 thus formed were filled with High Density Plasma (HDP) SiO₂ 202, as shown in FIG. 2b. This is followed by a planarization process, including a chemical-mechanical polishing (CMP) process, (FIG. 2c), followed by a combination of dry and wet etching step (FIG. 2d). Details of the planarization process will be described below.

As described above, after forming the Si holes, an HDP technique is used to fill the holes in the example embodiment. This advantageously avoids void formation inside the photonic crystal holes.

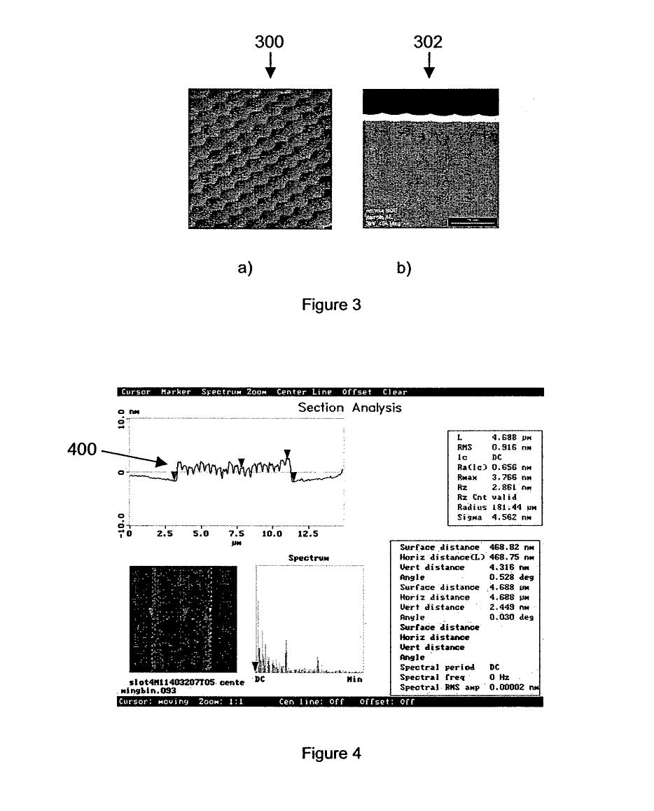

FIGS. 3a and b show top and cross-sectional view scanning electron microscopy (SEM) images 300, 302 respectively of the HDP oxide filled PhC holes in an example embodiment, illustrating the void-free holes, i.e. eliminating air-gaps in the PhC.

The deposition thickness to fill the holes completely for the entire matrix of holes which had different hole dimensions, as mentioned above, was optimized at 5000 Å for the example embodiment.

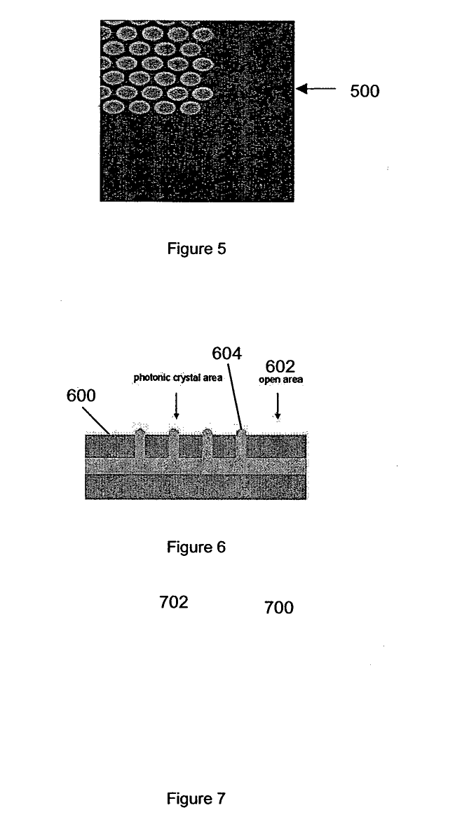

In the absence of a stop layer in the example embodiment (unlike in the conventional STI process flow), it is not possible to planarize the oxide filled photonic crystals with no loss of top silicon. However, it is important not to introduce recesses/roughness into the top silicon as the thickness and planarity of the PhC slab is crucial. In the example embodiment, part of the top silicon di-oxide (—3500 Å) is initially planarized partially by a chemical-mechanical polishing (CMP) process. The subsequent planarization is achieved by using a combination of plasma dry etch and a final wet chemical etching of the oxide layer. Excellent planarity of <10 nm was achieved for the PhC slab which was measured by Atomic Force Microscopy (AFM) scan 400 as shown in FIG. 4. FIG. 5 shows a top view SEM image 500 of the PhC slab after the final wet etching with <10 nm planarity.

The inventors have recognized that after the CMP partial planarization, performing a plasma dry etch to stop on the top silicon can cause surface damage resulting in surface roughness and also loss of Si depending on selectivity. Instead, in the example embodiments the oxide removal is performed using partially dry plasma etching followed by wet chemical etching, or using only a wet chemical etch alone. It was found that the etch rate of silicon di-oxide is less at the photonic crystal area compared to that on top of the open area (silicon). Consequently when the oxide etching was stopped after reaching Si 600 at the open area 602, left over oxide at the photonic crystal area formed semi-circular protrusions 604, as shown in FIG. 6. The high selectivity of e.g. HF wet etching chemical to silicon in the example enables continued etching to further remove the remaining oxide protrusions 604 at the photonic crystal area, providing sufficient process margins. Flatness of <10 nm at both open and photonic crystal areas 700, 702 within the device area, in other words the PhC slab, are achieved, as shown in FIG. 7. In the example embodiment, the oxide dry plasma etching was done using C₄F₈ based gas mixture and the final wet etching was done by diluted Hydro-Fluoric acid solution.

It was found that HF wet etching does remove some of the silicon (several angstroms) and does not introduce significant surface roughness. More over, performing the oxide final removal by wet etching in the example embodiment is advantageous as the wet etch selectivity to Si is found to be higher than for dry etch. This preferably gives the flexibility to perform over etch by wet etching in order to remove any remaining oxide on the Si surface without losing a significant amount of oxide inside the PhC. It is believed that the removal of oxide inside the PhC is limited due to a difference in topography of the open area and the crystal hole area, thus being advantageously able to maintain the surface planarity of <10 nm in the example embodiment.

As the planarity of the PC slab is highly critical for further device fabrication on the slab and optical performance of such built-on devices, the fully controllable and repeat-able processes demonstrated in the example embodiments illustrate the potential of the embodiments for various applications. This is further facilitated by the robust, CMOS compatible process integration approach of the example embodiments.

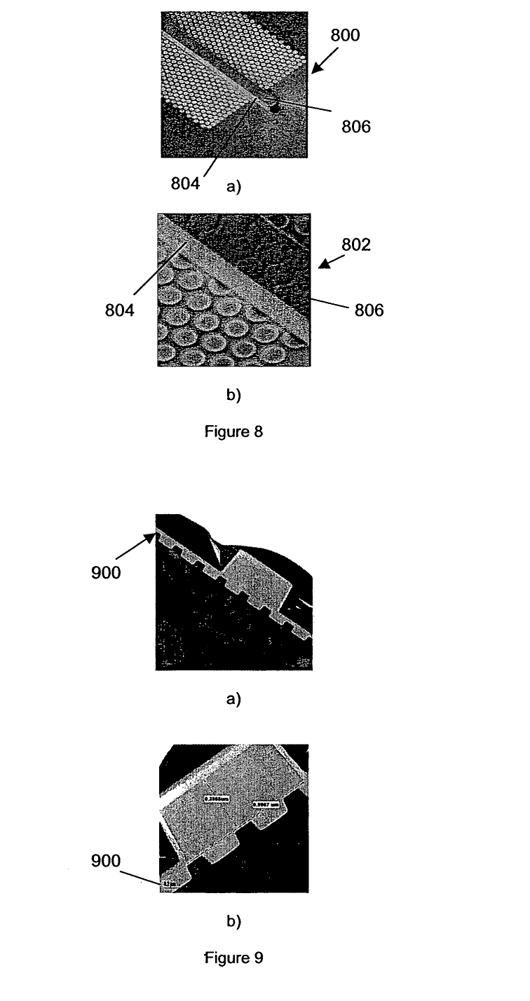

To demonstrate the subsequent process integration capability for device fabrication, formation of silicon nitride waveguides on a PhC slab of an example embodiment was performed. The Phc slab was patterned for waveguide structures after depositing a silicon nitride layer. Stringent optical device requirements offer greater challenges for an etch process to achieve vertical waveguide profile and smooth sidewalls. Moreover, in case of a PhC slab as the substrate, precise control of the etch stop is required to soft land on the PhC slab with negligible loss of top Silicon and also silicon di-oxide present at the photonic crystal areas. The silicon nitride was etched using a CF₄/O₂ based gas combination to form the waveguide. Optimized etch process performance was achieved by using end point based etching to have a good etch stop on the PhC. The etch process was optimized for good uniformity and repeat-ability within the wafer and batch. Tilted sidewall SEM images 800, 802 as shown FIGS. 8a and b revealed smooth sidewalls 804 of the silicon nitride waveguide 806, which is crucial to achieve good optical performance of the device.

Transmission electron microscopy (TEM) analysis after Si₃N₄ waveguide formation showed no recessing into the bottom photonic crystals or PhC slab 900 (which consists of both Silicon and Silicon di-oxide surfaces) as shown in FIGS. 9a and b, confirming the precise control of the silicon nitride wave guide etching.

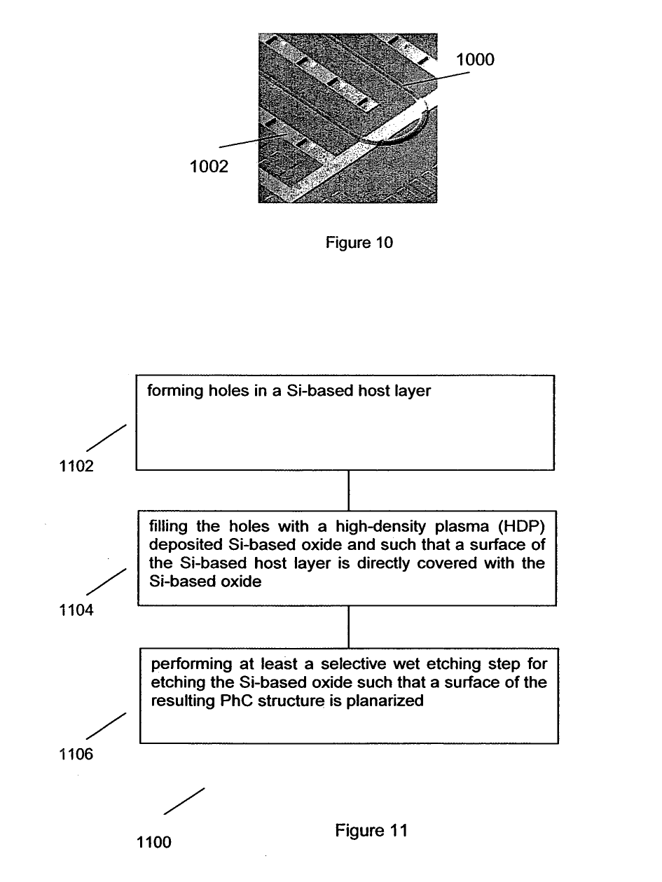

After completing the formation of waveguide structures on the PhC slab, bi-level aluminium metal contacts were also formed, demonstrating the feasibility of the PhC based photonic device integration in the example embodiment. FIG. 10 shows an SEM image of the physical structure of a photonic device in the example embodiment after completing the fabrication using PhC as the substrate, showing a waveguide 1000 and aluminium bi-level metal contacts traces e.g. 1002. The PhC structure is located under the waveguide 1000 in this example embodiment.

The example embodiments described provide a fabrication method of forming photonic crystal based slabs using a fully CMOS compatible process. Void-free photonic crystal structures eliminating the air gap and with excellent surface planarity can be achieved. Optical grade PhC slabs with <10 nm planarity can be achieved. The feasibility of subsequent device integration was demonstrated through the fabrication of silicon nitride waveguides, with aluminium bi-level metal contacts. The device platform of example embodiments can be used for optical and/or opto-electrical devices such as—Modulators, High Q cavities for light sources, and chromatic dispersion compensators. Process modules used in the integration scheme of the example embodiments are capable of providing excellent process control. This enables a manufacturable technology platform to mass produces advanced photonics devices with lower costs.

FIG. 11 shows a flowchart 100 illustrating a method of forming a photonic crystal structure according to an example embodiment. At step 1102, holes are formed in a Si-based host layer. At step 1104, the holes with a high-density plasma (HDP) deposited Si-based oxide and such that a surface of the Si-based host layer is directly covered with the Si-based oxide. At step 1106, at least a selective wet etching step is performed for etching the Si-based oxide such that a surface of the resulting PhC structure is planarized.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method of forming a photonic crystal (PhC) structure, the method comprising the steps of:
forming holes in a Si-based host layer;
filling the holes with a high-density plasma (HDP) deposited Si-based oxide and such that a surface of the Si-based host layer is directly covered with the Si-based oxide;
performing at least a selective wet etching step for etching the Si-based oxide such that a surface of the resulting PhC structure is planarized.

2. The method as claimed in claim 1, wherein the host layer comprises Si.

3. The method as claimed in claim 1, wherein the Si-based oxide comprises SiO₂.

4. The method as claimed in claim 1, wherein the wet etching comprises an HF etching.

5. The method as claimed in claim 1, further comprises performing a partial dry etching step prior to the wet etching step.

6. The method as claimed in claim 5, wherein the dry etching step comprises a plasma-etching step.

7. The method as claimed in claim 1, further comprising performing a chemical-mechanical polishing (CMP) step prior to the wet etching step.

8. The method as claimed in claim 5, wherein the CMP step is performed prior to the dry etching step.

9. The method as claimed in claim 1, further comprising forming at least one optical device structure directly on the planarized surface of the PhC structure.

10. The method as claimed in claim 1, further comprising forming one or more metal contacts directly on the planarized surface of the PhC structure.

11. The method as claimed in claim 1, wherein the surface of the resulting PhC structure is planarized to below about 10 nm.

12. A PhC structure fabricated using a method as claimed in claim 1.
